(19) United States
(12) Patent Application Publication
(10) Pub. No.: US 2018/0006254 A1
(43) Pub. Date: Jan. 4, 2018

(54) CRYSTALLINE PEROVSKITE THIN FILMS AND DEVICES THAT INCLUDE THE FILMS

(71) Applicant: Los Alamos National Security, LLC, Los Alamos, NM (US)

(72) Inventors: Aditya Mohite, Los Alamos, NM (US); Gautam Gupta, Los Alamos, NM (US); Hsing-Lin Wang, Los Alamos, NM (US); Wanyi Nie, Los Alamos, NM (US)

(21) Appl. No.: 15/539,422

(22) PCT Filed: Dec. 23, 2015
(86) PCT No.: PCT/US15/00316

§ 371 Date: Jun. 23, 2017

Related U.S. Application Data
(60) Provisional application No. 62/096,375, filed on Dec. 23, 2014.

(51) Int. Cl. H01L 51/42; H01L 51/00

(52) U.S. Cl. CPC H01L 51/424; H01L 51/009; H01L 51/0047; H01L 51/0003; H01L 51/0037; H01L 51/0026; H01L 51/004

(57) ABSTRACT

Hybrid organic-inorganic perovskite thin films with average grain sizes of at least 50 micrometers were prepared and employed in solar cells. The PCE values of the solar cells did not degrade with the direction or the scan-rate of the applied voltage. The larger average grain sizes are believed to assist in reducing the influence of defect states on carrier recombination. The tunability of PCE with substrate temperature may be correlated to the quality of the crystalline perovskite formed using the hot-casting procedure. The larger average grain sizes lead to good crystalline quality, low defect density, and high carrier mobility. The process for growing hybrid organic-inorganic perovskites may be applicable to the preparation of other materials to overcome problems related to polydispersity, defect formation, and grain boundary recombination.

### CROSS REFERENCE TO RELATED APPLICATIONS

This application is a National Phase Patent Application, and claims priority to and the benefit of International Patent Application Number PCT/US2015/000316, filed on Dec. 23, 2015, which claims priority of U.S. Provisional Patent Application No. 62/096,375 filed Dec. 23, 2014, the entire contents of all of which are incorporated herein by reference.

### STATEMENT REGARDING GOVERNMENT RIGHTS

The United States government has rights in this invention pursuant to Contract No. DE-AC52-06NA25396 between the United States Department of Energy and Los Alamos National Security, LLC for the operation of Los Alamos National Laboratory.

### FIELD OF THE APPLICATION

The present application generally relates to the field of thin films and devices that include thin films, and more particularly to a method of preparing thin films of crystalline perovskites and to devices such as solar cells that include the perovskite films.

### BACKGROUND

The power conversion efficiencies (PCEs) of some known conventional thin films of certain perovskites known in the art as hybrid organic-inorganic perovskites are higher than those of semiconductors used in state-of-the-art photovoltaic devices. Thin films of CH₃NH₃PbX₃ (X═Cl, Br, I), in particular, have been prepared with power conversion efficiencies (PCEs) as high as 19%. The high PCEs of these perovskite thin films have been attributed to strong light absorption and weakly bound excitons that easily dissociate into free carriers with large diffusion length. Defect-induced hysteresis has been identified as a bottleneck to the production of stable, reproducible devices. Recent efforts have focused on improving film surface coverage, crystal size, and quality of the crystalline grains. Approaches such as rapid thermal annealing have been investigated.

Control of the structure including the morphology, grain size, and degree of crystallinity remains a challenge for preparing hybrid organic/inorganic perovskites for devices such as solar cells. Therefore, a need exists for a thin film device of hybrid organic-inorganic perovskites, and a method of preparing the same, that overcomes the above limitations and provides stable, reproducible thin film devices.

### SUMMARY

In some embodiments, a device has been prepared by a process that includes forming a layer of a charge transport material on a transparent conducting substrate and heating the substrate to a temperature of at least 100° C. An aged composition is formed by mixing together at least one lead halide compound, methylamine, and a solvent, and then aging the composition at a temperature of at least 50° C. for at least 24 hours. A layer of the aged composition is formed by coating onto the layer of charge transport material. The layer of aged composition is converted to a solid layer of perovskite CH₃NH₃PbIₓCl₃₋ₓ wherein 0≦x≦3. The solid layer of perovskite has crystalline grains with an average grain size of at least 50 micrometers. A second layer of charge transport material is formed on the solid layer of perovskite, and an electrode layer is formed on the second layer of charge transport material.

In some embodiments, a process for preparing devices such as solar cells with power conversion efficiencies that do not degrade with varying the scan rate or direction of a voltage applied to the solar cells, is disclosed. The process includes forming a layer of a charge transport material on a transparent conducting substrate. The substrate is heated to a temperature of at least 100° C. An aged composition is prepared by mixing at least one lead halide compound and methylamine in a solvent and thereafter aging the composition at a temperature of at least 50° C. for at least 24 hours. A layer of the aged composition is formed on the first charge transport material. The layer of aged composition is converted to a solid layer perovskite CH₃NH₃PbIₓCl₃₋ₓ wherein 0≦x≦3. The solid layer of perovskite has crystalline grains with an average grain size of at least 50 micrometers. Afterward, a second layer of a charge transport material is formed on the solid perovskite layer, and an electrode layer is formed on the second layer of charge transport material.

In some embodiments, a solar cell having a power conversion efficiency (PCE) that does not degrade with varying the scan rate or direction of an applied voltage to the solar cell was prepared by a process including forming a layer of poly(3,4-ethylenedioxythiophene):polystyrene sulfonic acid (PEDOT:PSS) on a substrate of optically transparent material, is disclosed. The substrate was heated at a temperature of at least 100° C. An aged composition was formed by mixing a 1:1 molar ratio of lead iodide and methylamine and aging the composition by stirring it at a temperature of at least 50° C. for a period of time of at least 24 hours, and afterward a layer of the now aged composition was formed on the preheated PEDOT:PSS layer and converted to a solid layer of the perovskite CH₃NH₃PbIₓCl₃₋ₓ, wherein 0≦x≦3, and having crystalline grains with an average grain size of at least 50 micrometers. After forming the layer of solid perovskite, a layer of [6,6]-phenyl-C₆₀ butyric acid methyl ester (PCBM) was formed on the perovskite and then an electrode layer was formed on the layer of PCBM.

Various advantages of the present application are apparent in light of the descriptions below.

### BRIEF DESCRIPTION OF THE DRAWINGS

FIG. 1A through FIG. 1C illustrate a conventional post-annealing process for preparing thin films of perovskites.

FIG. 2A through FIG. 2C illustrate a process for preparing thin films of perovskites in accordance with some embodiments.

FIG. 3 is a schematic diagram illustrating a perspective view of a planar device configuration of a solar cell in accordance with some embodiments.

FIG. 4 is an optical microscopy image of a perovskite thin film in accordance with some embodiments, including random lines that were used in a standard procedure for determining grain sizes of over optical microscopy images.

FIG. 5 is a chart comparing average grain sizes of perovskite films that were obtained at different processing temperatures using a conventional post-annealing process versus a hot casting process in accordance with some embodiments.

FIG. 6 is a chart comparing average grain sizes of perovskite films obtained by using a hot casting process in accordance with some embodiments versus a conventional post-annealing process, using different aging times for the casting solution.

FIG. 7A shows a scanning electron microscope (SEM) image of a conventional perovskite film that was spin casted at room temperature without any annealing.

FIG. 7B shows an SEM image of a perovskite film that was prepared by conventional spin casting at room temperature followed by annealing at 100° C. for 20 minutes.

FIG. 7C is an SEM image of the thin film that was spin casted at 150° C., in accordance with some embodiments. Unlike the SEM images of FIGS. 7A and 7B, this SEM image shows a leaf-like structure within each grain of the perovskite thin film.

FIG. 8A shows X-ray diffraction (XRD) spectra of perovskite thin films prepared by a conventional post annealed process.

FIG. 8B shows XRD spectra of perovskite films that were prepared by hot casting solutions onto surfaces preheated at 180° C., in accordance with some embodiments. The solutions were aged from 1 hour to 10 days. The triangle refers to perovskite main peak, and they are both indicative of the desired perovskite phase. They are the first and second order of the peak (position of second peak is at an angle two times that of the first peak—triangle on left of screen). The diamond refers to PbMACl₃ peaks.

FIG. 9A and FIG. 9B show XRD spectra that illustrate conversion to perovskite from what is believed to be an intermediate phase. FIG. 9a shows XRD spectra for conventional as-cast films with post annealing from 50° C. to 110° C. FIG. 9b shows XRD spectra for thin films hot casted on surfaces preheated at temperatures from 50° C. to 190° C., in accordance with some embodiments.

FIG. 9C shows a graph of XRD peak ratio versus processing temperature for a conventional post annealing process (squares) and the hot casting process in accordance with some embodiments (circles).

FIG. 10A shows a normalized absorbance spectrum (black) and a microscopically resolved photoluminescence spectrum (red) for a thin film in accordance with some embodiments.

FIG. 10B shows a first derivative of the absorbance also plotted against energy, which provides a good visualization of the evolution of the band-edge with respect to the average grain size.

FIG. 11 shows normalized, microscopically resolved emission spectra for the thin films of different grain sizes in accordance with some embodiments.

FIG. 12 shows relative shift and line width broadening of the band-edge emission as a function of grain area (with respect to the largest grain) for the thin film in accordance with some embodiments.

FIG. 13 shows normalized microscopically resolved time correlated single photon histograms of both a large grain and a small grain, in accordance with some embodiments. The red and black lines are fits to the intensity decay considering interband relaxation, radiative bimolecular recombination, and non-radiative decay into trap states below the gap.

FIG. 14 shows J-V curves obtained under AM 1.5 illumination, for the thin film in accordance with some embodiments.

FIG. 15 provides a plot of overall PCE (left) and J_{sc} (right) versus substrate temperature for the hot casting process in accordance with some embodiments.

FIG. 16 shows average J-V characteristics for the thin film in accordance with some embodiments, that resulted by sweeping the voltage from forward bias to reverse bias, and from reverse bias to forward bias. These curves were obtained by averaging 15 sweeps in each direction.

FIG. 17 shows J-V curves at different voltage scan rates in volts/sec for the thin film in accordance with some embodiments.

FIG. 18 describes the variation in the PCE from measurements taken from 50 thin film devices in accordance with some embodiments.

FIG. 19 is a flowchart illustrating a process for preparing a perovskite device in accordance with some embodiments.

### DETAILED DESCRIPTION

Reference will now be made in detail to embodiments, examples of which are illustrated in the accompanying drawings. In the following detailed description, numerous specific details are provided to provide a full understanding of the subject matter presented herein. It will be apparent, however, to one skilled in the art that the subject matter may be practiced without these specific details. In other instances, well-known methods, procedures and components have not been described in detail to avoid unnecessarily obscuring aspects of the embodiments.

In some embodiments, a thin film of hybrid organic-inorganic perovskites composed of crystalline grains having an average grain size of at least 50 micrometers was prepared by a process including casting a solution on a hot substrate surface followed by slow cooling to form a thin film of solid perovskite. The thin film is composed of crystalline grains having grain sizes that may be controlled predictably by modifying the aging time of the solution, the casting solvent, and by controlling the rate of evaporation of the solvent, which allow for sufficient time for the large crystalline grains to form.

In some embodiments, devices such as solar cells including such perovskite films were prepared. These solar cells had power conversion efficiencies (PCEs) of from about 14% to about 16%, and a solar cell with a PCE of 18% was prepared. The high PCEs are believed to be due to an increase in charge carrier mobility and a reduction in defect densities. The current density of the perovskite thin films of the solar cells in accordance with some embodiments did not degrade with changes in voltage sweep direction or with changes in the rate at which the voltage was scanned.

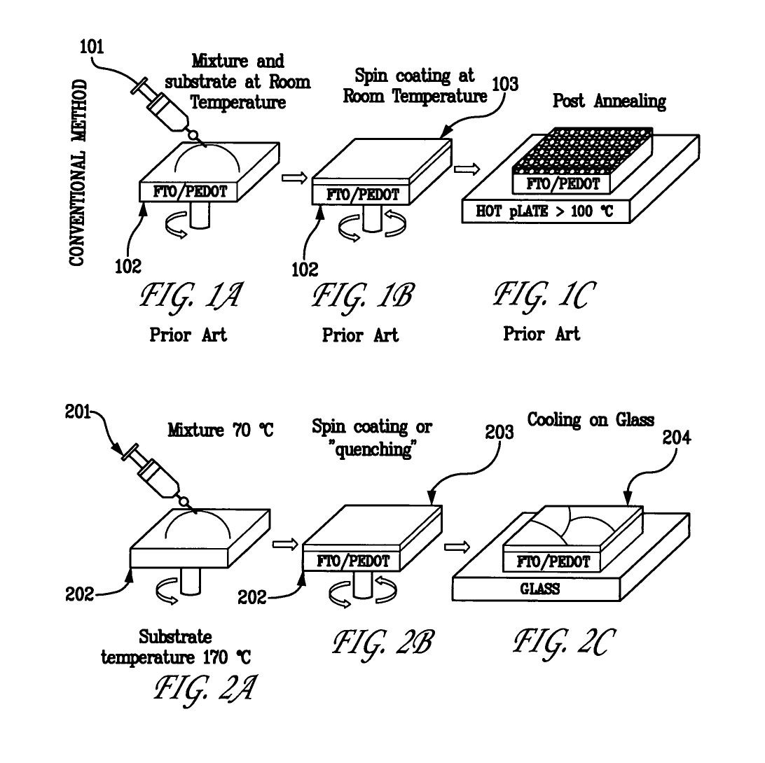

FIGS. 1A, 1B and 1C illustrate schematically a known, conventional post-annealing process for preparing a hybrid organic-inorganic perovskite thin film. This conventional process involves casting a room temperature solution of lead iodide (PbI₂) and methylamine hydrochloride (MACl) 101 on a room temperature, supported, ion conducting layer 102 (FIG. 1A), and then spin-coating the solution on the ion-conducting layer 102 to form a film 103 (FIG. 1B), and then annealing the film 103 for 20 minutes at a temperature above 100° C. (FIG. 1C).

A process for preparing hybrid organic-inorganic perovskite thin films in accordance with some embodiments is shown schematically in FIGS. 2A, 2B, and 2C. Unlike the conventional process, the process in accordance with some embodiments involves casting a hot solution 201 with a solution temperature typically from about 50° C. to about 100° C. (in the example here, about 70° C.) of PbI₂ and methylamine hydrochloride onto a substrate-supported layer of a charge transport material 202. The substrate (not shown) and layer 202 thereon have been preheated to a temperature of at least 100° C. (in the example shown in FIG. 2A, preheated to about 170° C.). In this embodiment, the solution 201 is spin coated onto the charge transport layer 202 to form a uniform film 203 (FIG. 2B), and then cooled slowly to form the perovskite film 204 (FIG. 2C).

It should be understood that the processes in accordance with the embodiments are not limited to spin coating, and that other coating techniques such as, but not limited to, spray coating, draw blading, roll-to-roll, ink-jet printing, dip-coating, and the like may also be used.

It should also be understood that, while the example devices including the perovskite films in accordance with some embodiments that are presented in greater detail herein are with respect to solar cell embodiments, the process for forming perovskite films in accordance with some other embodiments, e.g., using a hot solution of at least one halide and methylamine hydrochloride and a solvent, may also be used for preparing other embodiment devices including, but not limited to, light emitting diodes (LEDs), field effect transistors (FETs), memory devices, photo-detectors, photo-transistors, optical sensors, biosensors, and the like, which are all devices that include an element that may be a solid perovskite film of the formula CH₃NH₃PbIₓCl₃₋ₓ wherein 0≦x≦3, and the solid perovskite layer has crystalline grains with an average grain size of at least 50 micrometers. Devices with the perovskite films in accordance with the embodiments have advantages resulting from the perovskite films and the preparation processes in accordance with some embodiments that will be described later.

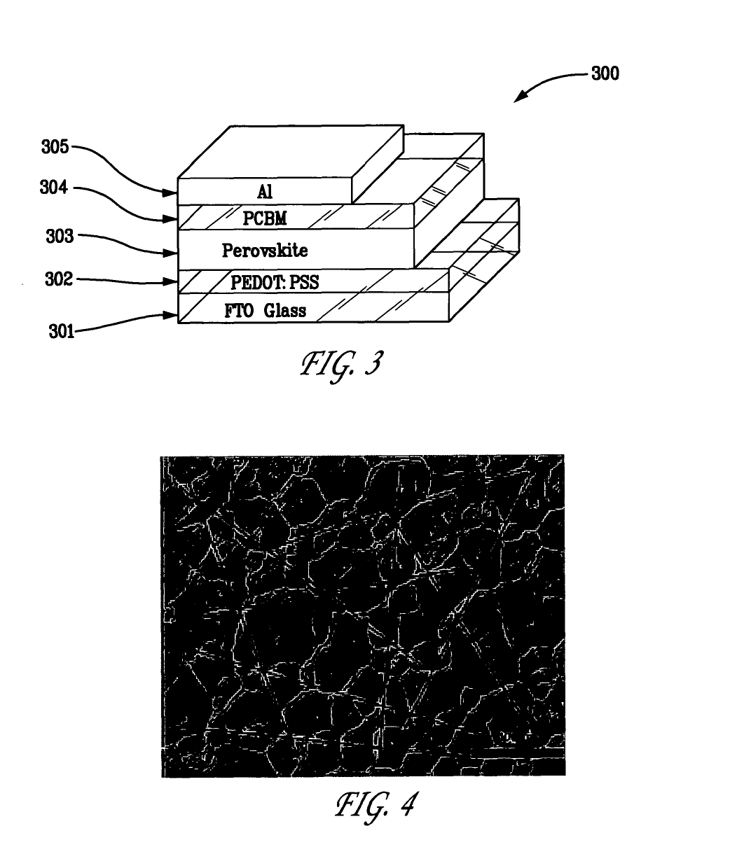

FIG. 3 illustrates the layered structure of a hybrid organic-inorganic perovskite-containing solar cell 300 in accordance with some embodiments, including an FTO glass electrode 301 (i.e. the substrate), a charge transport layer of 3,4-ethylenedioxythiophene)poly(styrenesulfonate) (PEDOT:PSS) 302, a perovskite layer (e.g., CH₃NH₃PbI₃) 303, another charge transport layer of [6,6]-phenyl-C₆₀ butyric acid methyl ester (PCBM) 304, and an electrode 305 (in the embodiment shown, an electrode of aluminum). Conventional devices with a kind of layered structure are already known (see Kim et al., “Mixed solvents for the optimization of morphology in solution-processed, inverted-type perovskite/fullerene hybrid solar cells,” Nanoscale, 2014, vol. 6, pp. 6679-6683, incorporated by reference). However, the solar cell in accordance with present embodiments differ from these known devices in aspects related to the perovskite layer, including the processes of making the perovskite layer in accordance with some embodiments, and the properties of the perovskite layer that are believed to result from the processes. It has been demonstrated that the solar cells including perovskite films in accordance with the present embodiments disclosed herein perform better than known devices. The performance includes a combination of high values of PCE and a current density that does not degrade with changes in sweep direction or rate of scan of an applied voltage.

It should be understood that, while the solar cell devices 300 in accordance with some embodiments presented herein have been prepared using a charge transport layer of PEDOT:PSS 302, which is a p-type charge-conducting material, other p-type charge conducting materials may be used instead such as, but not limited to, the following: poly(3-hexylthiophene-2,5-diyl) (P3HT); oligothiophene; 2,2′,7,7′-Tetrakis-(N,N-di-4-methoxyphenylamino)-9,9′-spirobifluorene; nickel oxide (Spiro-oMeTAD); vanadium(V) oxide (V₂O₅); tungsten trioxide (WO₃); molybdenum trioxide (MoO3); copper(I) thiocyanate; poly[N,N′-bis(4-butylphenyl)-N,N′-bis(phenyl)-benzidine] (polyTPD); N,N′-Bis(3-methylphenyl)-N,N′-diphenylbenzidine (TPD).

Similarly, it also should be understood that, while the solar cell devices 300 in accordance with some embodiments presented herein have been prepared using a charge transport layer of [6,6]-phenyl-C₆₀ butyric acid methyl ester (PCBM) 304, which is an n-type conducting layer, there are other materials that may be used that are also n-type conducting layers, including, but are not limited to: fullerene or other fullerene derivatives including but not limited to C60, PC60BM, C70 or PC70BM; zinc oxide; titanium oxide; and Bathocuproine.

### Preparation of Embodiments

FIG. 19 is a flowchart illustrating a process for preparing a perovskite device in accordance with some embodiments. In some embodiments, the substrates for solar cells include but are not limited to patterned fluorine-doped tin oxide (FTO) glasses. The substrates were cleaned in ultrasonication baths, first in a bath with deionized water, then in a bath with acetone, and then in a bath with isopropanol, each for a period of about 10 minutes. The substrates were then dried in air on a hot plate at 120° C. for 30 minutes, and afterward were cleaned using oxygen plasma for 3 minutes under a roughing vacuum.

Next, in step 1901, a layer of a charge transport material was formed on the clean substrate surface by spin-coating a solution of 3,4-ethylenedioxythiophene)poly(styrenesulfonate) (PEDOT:PSS, CLEVIOS® P VPAI 4083) on top of the clean FTO glass substrate at 5000 rotations per minute (rpm) for 45 seconds. This layer of PEDOT:PSS is also referred to herein as a hole-transporting layer (HTL). The FTO glass/PEDOT:PSS was dried in air on a hot plate at 120° C. for 30 minutes. After drying, the FTO glass/PEDOT:PSS was transferred to an argon-filled glove box for the spin-coating of the other layers.

The hybrid organic-inorganic perovskite thin film was formed on the FTO/PEDOT-PSS as follows. A solution containing PbI₂ and methylamine hydrochloride (MACl) at a temperature of at least 50° C. (generally from about 50° C. to about 100° C.) was prepared. The MACl was synthesized by dissolving 10 milliliters (ml) of methylamine (33 weight percent in absolute ethanol) in 50 ml of diethyl ether in a 100 ml round-bottomed flask in an ice bath for 30 minutes, followed by adding 12 ml of hydrochloric acid (HCl, 37 weight percent in water) dropwise. The white precipitate that formed was collected and washed three times with diethyl ether and then dried at 80° C. in a vacuum oven overnight. The PbI₂ (PbI₂, >99.99%, SIGMA-ALDRICH, MW=461.01 g/mol) was used without further purification.

Casting solutions were prepared by combining PbI₂ and dimethylformamide (DMF) in a molar ratio of 1:1, in step 1903, followed by aging on a hot plate at a temperature of at least 50° C. in step 1904. Although described herein with pure PbI₂, it should be understood that the present process for preparing hybrid organic-inorganic perovskite films may be applied to both pure (e.g., mixture of PbI₂ and MAI) and mixed halide perovskite combinations (e.g., mixture of PbI₂ and PbCl₂ or PbCl₂ and MAI), and it may be thought of as a starting point for the realization of industrially scalable large area crystalline thin films of other materials such as CZTs, CIGs and the like using low temperature solution-processed large-area crystal growth. It should also be understood that the solvent used for the casting solutions is not limited to any particular one, but that the boiling point is preferably greater than 130° C. Thus, besides DMF (boiling point approximately 150° C.), other solvents for preparing the casting solution include N-methyl-2 pyrrolidone (NMP, boiling point approximately 200° C.) and γ-butyrolactone (boiling point approximately 204° C.).

Prior to casting, the solution was aged. Aging in the present process according to some embodiments includes stirring the solution on a hot plate while heating the solution at a temperature of at least 50° C. The effects of aging conditions on average grain size were examined by varying the aging temperature and aging period (from about 1 hour to about 240 hours) until casting. The results suggest that aging the solution appropriately prior to casting may facilitate the formation of larger average grain sizes. For example, an average grain size of at least 50 micrometers may be obtained by casting a solution that was aged by stirring at a temperature of at least 50° C. (e.g., 65° C.) for from 1 hour to 24 hours (see. e.g., step 1904). In a process according to one embodiment, prior to casting, the substrate was pre-heated on a hot plate to a temperature of at least 100° C., in step 1902.

Immediately after casting, in step 1905, the spin-coating began, typically at 5000 rpm. A few seconds after the spin coating began, the color of the film changed from yellow to dark brown, in step 1906.

Next, in step 1907, a charge transport layer of PCBM was formed on the perovskite layer by spin coating a solution of PCBM (20 mg/ml in chlorobenzene) on the perovskite layer at room temperature at 1000 rpm for 45 seconds to form a 20 nm-thick layer of PCBM. The PCBM layer is a second conducting layer, otherwise referred to herein as an electron transporting layer (ETL).

Next, in step 1908, the assembly of FTO/PEDOT:PSS/perovskite/PCBM was transferred to a thermal evaporation chamber. The chamber was pumped down to 1×10⁻⁷ ton, and a layer of aluminum (e.g., 100 nm in thickness) was deposited onto the PCBM layer through a shadow mask that defined the device active area for the solar cell. Other suitable metals (for an electrode) besides aluminum may be used, including but not limited to gold and silver.

### Measuring the Grain Size of the Perovskite Films

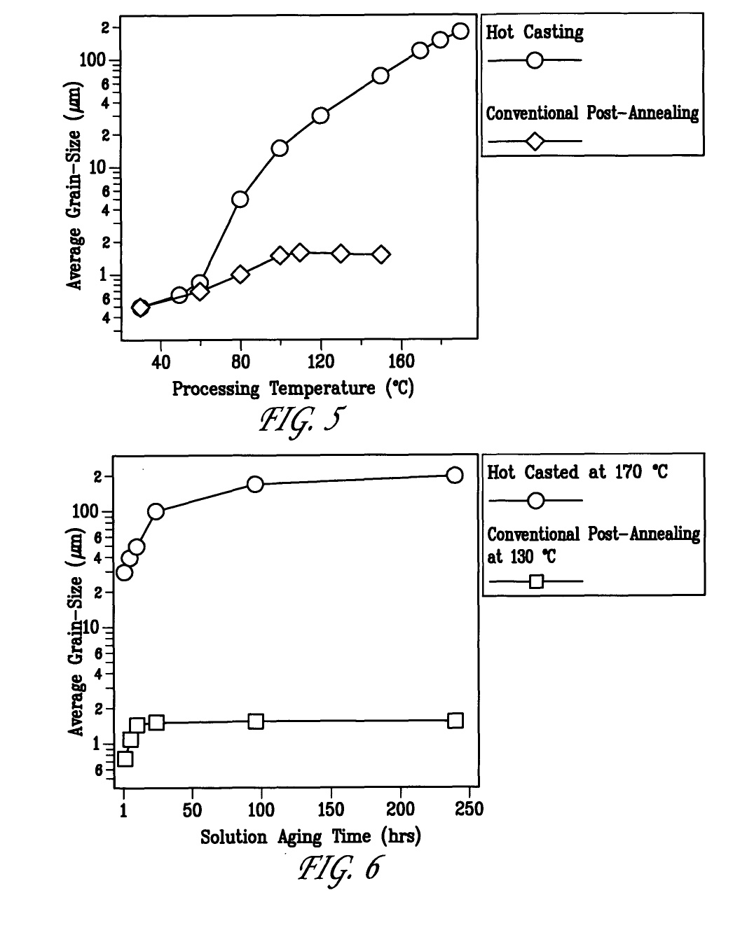

Prior to depositing the PCBM layer, the average grain size of the perovskite film may be determined using a suitable procedure such as an ASTM procedure that is a standard procedure of determining grain size over optical microscopy images. The average grain size for each of the perovskite films was determined using the ASTM E112 intercept procedure (4.1.3). This approach determines the grain size by using the following formula:

$$G = 6.643856 {log}_{10} \frac{{P}_{i}}{\frac{L}{M}} - 3.288$$

where G is the grain size number, Pᵢ is the total number of intercepts of all test lines, L is the total length of test lines, and M is the magnification. FIG. 4 shows an example of random lines used for counting the intercepts for an optical microscopy image of a perovskite thin film. A precision of better than ±0.25 grain size units is expected, and should be repeatable and reproducible within ±0.5 grain size units.

The evolution of film morphology and grain sizes with deposition conditions such as substrate temperature and solution aging time was examined. The results suggest that the sizes of the grains of the perovskite layer are affected by substrate temperature. FIG. 5 is a graph of average grain size versus processing temperature (i.e. substrate temperature). Average grain sizes were found to increase with increasing substrate temperature based on data obtained for substrate temperatures of 50° C., 70° C., 90° C., 100° C., 130° C., 150° C., 170° C., and 190° C.

FIG. 6 is a graph of average grain size versus solution aging time. Average grain sizes of the perovskite film were also found to increase with increasing aging time based on data obtained for solutions that were aged for 1 hour, 10 hours, 24 hours, 96 hours, and 240 hours prior to casting.

The results also suggest that solvents with boiling points of at least 130° C., such as, but not limited to, N,N-dimethylformamide (DMF) and N-methyl-2 pyrrolidone (NMP), are preferable for preparing the casting solutions.

Morphology of the film was also affected by casting conditions. FIG. 7A is a scanning electron microscope SEM image of perovskite film that was spin casted at room temperature without any annealing. FIG. 7B is an SEM image of a perovskite film that was spin casted at room temperature followed by annealing at 100° C. for 20 minutes. The microstructures shown in FIG. 7A and FIG. 7B are similar to what has been reported in the literature for perovskite films (See: You et al., “Low-Temperature Solution-Processed Perovskite Solar Cells with High Efficiency and Flexibility,” ACS Nano, 2014, vol. 8, pp. 1674-1680; and Wang et al., “Large fill-factor bilayer iodine perovskite solar cells fabricated by a low-temperature solution process,” Energy & Environmental Science, 2014, vol. 7, pp. 2359-2365, incorporated by reference).

FIG. 7C is an SEM image of a film that was cast according to a process in accordance with some embodiments, from an aged solution using a substrate preheated to 150° C. Unlike the films shown in FIGS. 7A and 7B, the perovskite film of FIG. 7C has a leaf-like structure within each grain of the film.

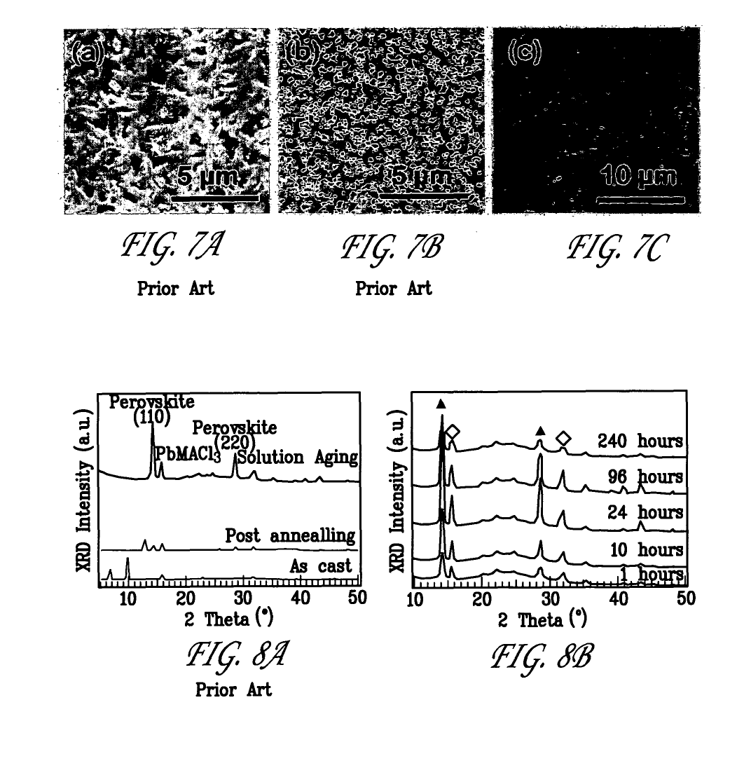

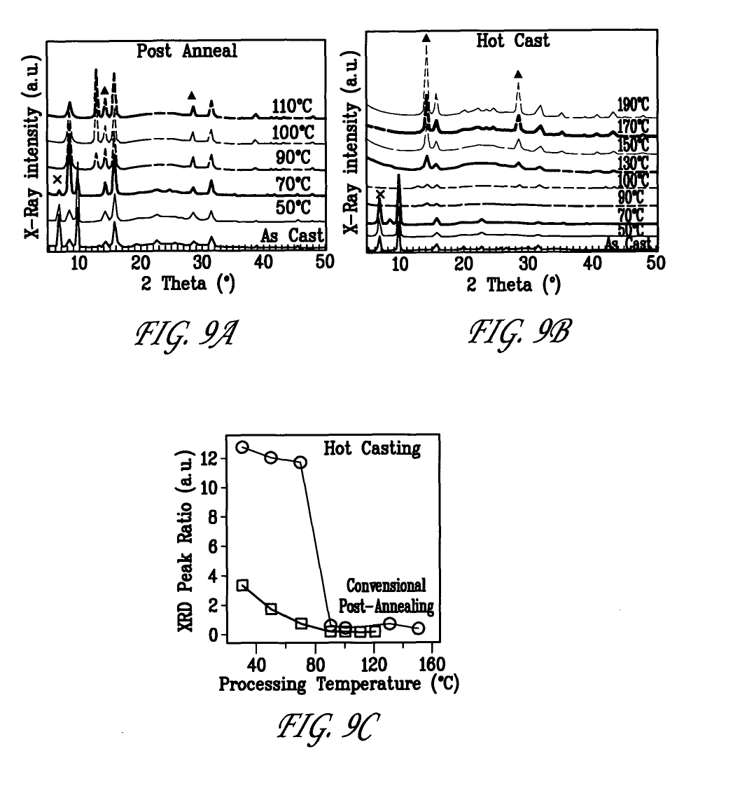

XRD spectra were obtained to compare the structures of films prepared using a conventional, post-annealing-type process with films prepared using a hot-casting process in accordance with some embodiments. FIG. 8A shows XRD spectra of perovskite films obtained by a conventional as-cast, post annealed process, while FIG. 8b shows XRD spectra of perovskite films obtained in accordance with some embodiments, which were hot cast at 180° C. using aging solution varying from 1 hour up to 10 days (the triangle refers to perovskite main peak; the diamond refers to PbMACl₃ peaks); the castings were on charge transport layers that were on ITO substrates. The major diffraction peaks, which appear in the spectra for values of 2 Theta greater than 10 degrees, correspond to the perovskite crystal structure and agree with those reported in the literature (see, for example: Lee et al., “Efficient Hybrid Solar Cells Based on Meso-Superstructured Organometal Halide Perovskites,” Science, 2012, vol. 338, pp. 643-647; and Colella et al., “MAPbI3-xClx Mixed Halide Perovskite for Hybrid Solar Cells: The Role of Chloride as Dopant on the Transport and Structural Properties,” Chemistry of Materials, 2013, vol. 25, pp. 4613-4618, both incorporated by reference herein). Low-angle peaks at 6.25 degrees were attributed to the perovskite-solvent (PbI₂-MACl-DMF) intermediate phase (see: Jeon et al., “Solvent engineering for high performance inorganic-organic hybrid perovskite solar cells,” Nat. Mater., 2014, vol. 13, pp. 897-903, incorporated by reference herein) which is subsequently converted to the perovskite phase.

FIG. 9A shows XRD spectra of films prepared on substrates preheated at different temperatures for a conventional, post annealing process, while FIG. 9B shows XRD spectra for hot casting process in accordance with some embodiments. These spectra show the evolution of the ratio of the low angle peak at 6.25 degrees to the perovskite peak at approximately 14.2 degrees. For the conventional spin-coated post-annealed film, there is a gradual conversion to the perovskite phase with increasing temperature, and this leads to the formation of small grains. By contrast, for the hot casted films in accordance with some embodiments, the XRD spectra show a sharp transition to the perovskite phase at approximately 80° C. it is believed that these differences in the evolution of the XRD peaks are caused by differences in the rate of evaporation of solvent above the crystallization temperature of the perovskite. See FIG. 9C. For the conventional process, which involves post-annealing of the casted film, most of the solvent escapes during spin coating. Post annealing of the dry film above the activation energy for perovskite formation leads to a spontaneous formation of the perovskite grains but the lack of solvent limits the diffusion growth of the crystal, which leads to smaller grains. By contrast, hot-casting of the aged solution in accordance with some embodiments provides an excess of solvent present above the crystallization temperature; this solvent slowly evaporates as the substrate and solvent cool with spin coating, allowing for the prolonged growth of crystalline grains, which results in larger grains of the perovskite.

Additional hot casting experiments were performed using DMF and NMP as solvents in casting solutions. The sizes of perovskite grains for films formed by hot casting a DMF casting solution and an NMP casting solution onto a substrate surface that were kept on a hot plate at 140° C., upon examination, support the theory that the crystal grain size may be controlled by controlling the rate of evaporation of solvent above the crystallization temperature.

The perovskite films were examined by absorption spectroscopy, micro-photoluminescence, and time-resolved photoluminescence. Micro- and time-resolved photoluminescence spectroscopy were performed with a microscopy set-up that focused a 440-nm radiation laser beam close to the diffraction limit and a scanning mirror system that allowed for precise location of the focal point onto the sample surface (resolution <250 nm). Photoluminescence spectra were obtained using a spectrograph (SPECTRA-PRO 2300i) and a CCD camera (EMCCD 1024B) yielding a maximum error of 0.2 nm on the emission spectra. Time-resolved photoluminescence measurements were performed with a time-correlated single photon counting module (PicoHarp 300) combined with an Avalanche Photo-Diode (MPD-SPAD). The laser diode was typically set to deliver 25 nanosecond pulses at 25 MHz and a fluence of 0.3 μJ/cm² and in this case the sample was excited at 2.84 eV (approximately 435 nm) with a line width of about 10 meV. Absorption spectroscopy was performed using a VARIAN CARY 500.

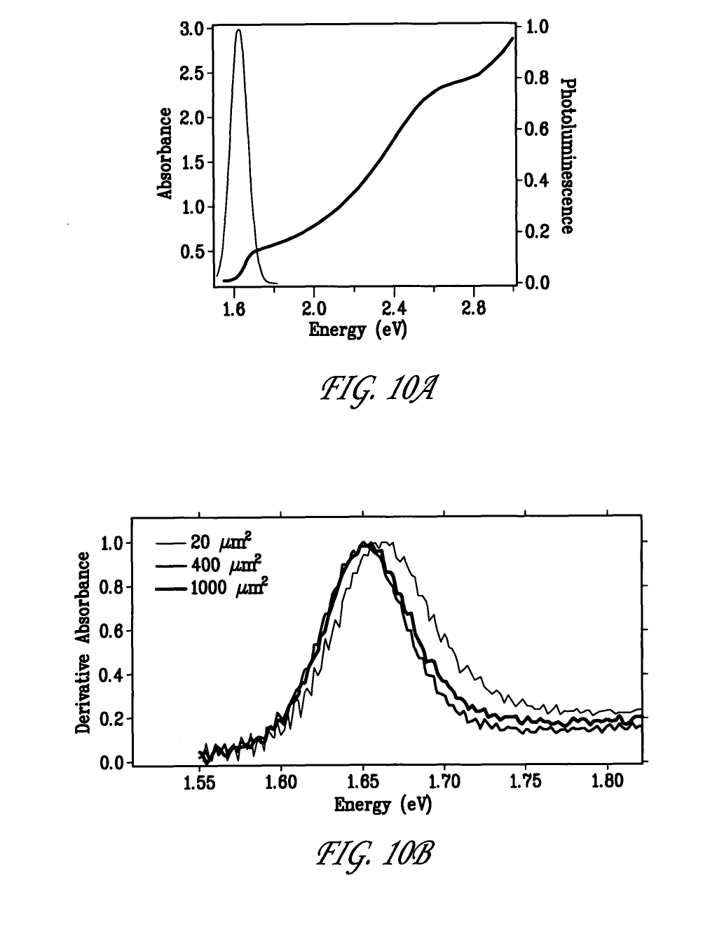

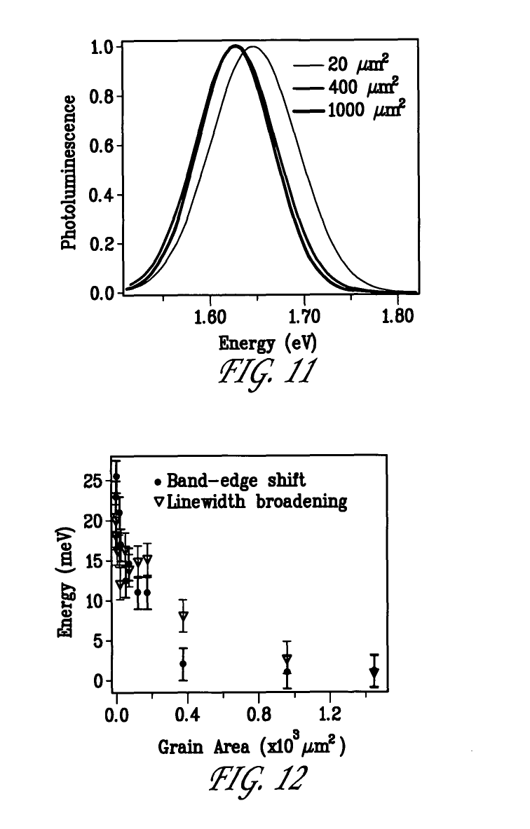

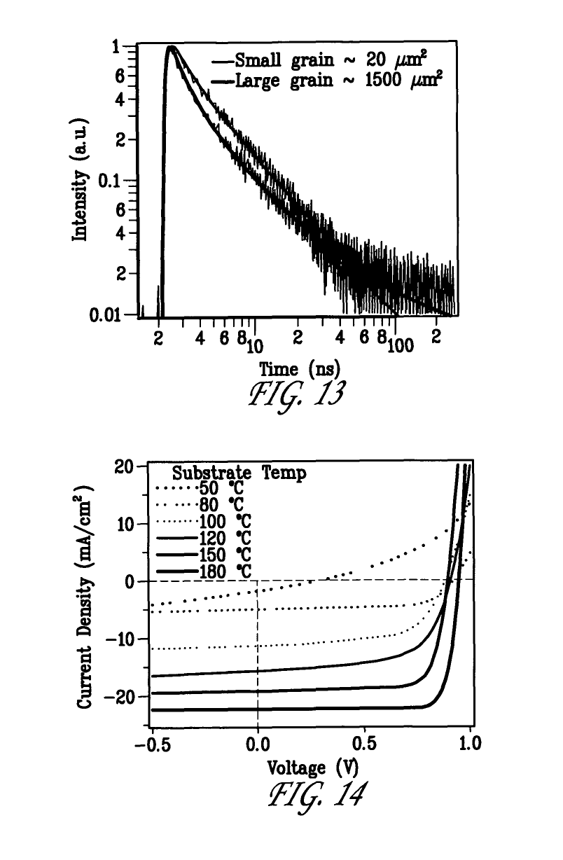

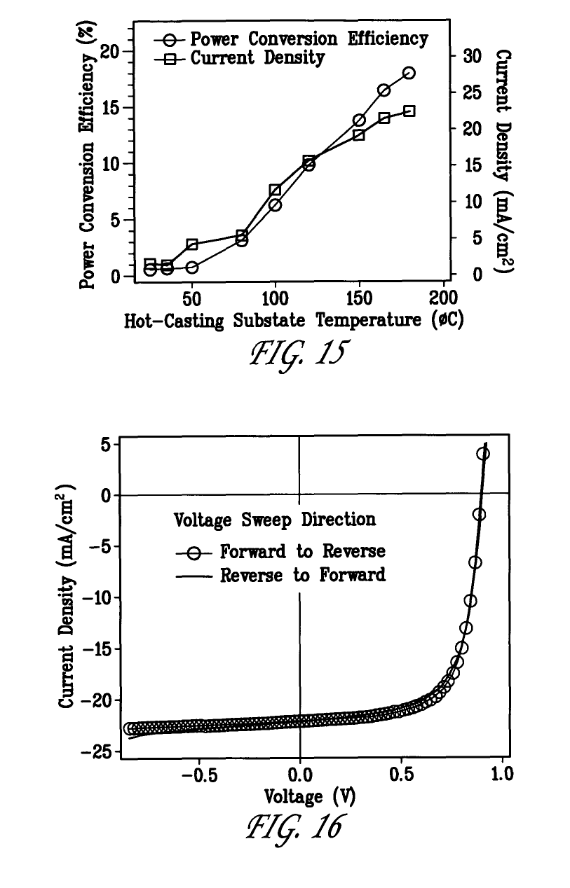

The crystalline perovskite films were characterized optically by micro-photoluminescence spectroscopy, absorption spectroscopy, and time-resolved photoluminescence spectroscopy. FIG. 10A shows a normalized absorbance spectrum (black) and a microscopically resolved photoluminescence spectrum (red) for an embodiment. Band-edge emission and absorption for grains larger than 1 mm² appeared at 1.627 eV and 1.653 eV respectively. FIG. 10B shows a first derivative of the absorbance also plotted against energy, which provides a good visualization of the evolution of the band-edge with respect to the average grain size. FIG. 11 shows normalized, microscopically resolved emission spectra for different grain sizes. As the grain sizes decreased, a blue shift of the band edge photoluminescence by approximately 25 meV was observed, as well as line width broadening of approximately 20 meV. Such blue shifts are attributed to an excess of Cl atoms at the grain boundaries. The increase of emission line-width at grain boundaries can be attributed to disorder and defects that extend into the inner grain regions for small grains but are localized near the grain boundaries for the large grains. FIG. 12 shows a plot showing relative shift and linewidth broadening of the band-edge emission as a function of grain area with respect to the largest grain. FIG. 13 shows a normalized, microscopically resolved time correlated single photon histograms of both a large and a small grain (black). The red and black lines are fits to the intrinsic intensity decay considering interband relaxation, radiative bi-molecular recombination, and non-radiative decay into states below the gap. We observed a bimolecular recombination process of free electrons and holes for the large grain size crystals. This contrasts a mono-exponential decay observed in previous reports for small grain sizes or mesoporous structures, which is consistent with our measurements on small grains and is representative of nonradiative decay due to trap sites.

Measurements for the solar cells in accordance with some embodiments, including measurements of the power conversion efficiency (PCE) took place at room temperature inside a vacuum chamber that was pumped down to 1×10⁻⁶ torr. A shadow mask confined a device area of about 0.035 cm² for cathode deposition. The same mask was used during device measurement to avoid edge effects for small area solar cells. Current-voltage sweeps were performed using KEITHLY 2100 unit under simulated air mass 1.5 irradiation (100 mW/cm²) using a xenon-lamp-based solar simulator (ORIEL LCS-100). A NIST calibrated monocrystalline silicon solar cell (NEWPORT 532, ISO1599) was used for light intensity calibration every time before measurement. The scan rate was set from 2 milliseconds to 1000 milliseconds range between −1 volts up to +1.5 volts with a step of 0.025 volts.

The external quantum efficiency was measured with a NIST calibrated monochromator (QEX10, 22562, PV measurement INC.) in AC mode. The light intensity was calibrated with a NIST calibrated photodiode (91005) as a reference each time before measurement. The monochromator was chopped at a frequency of 151 Hz. The integrated software will calculate quantum efficiency using measured photocurrent for the solar cell and the standard reference cell.

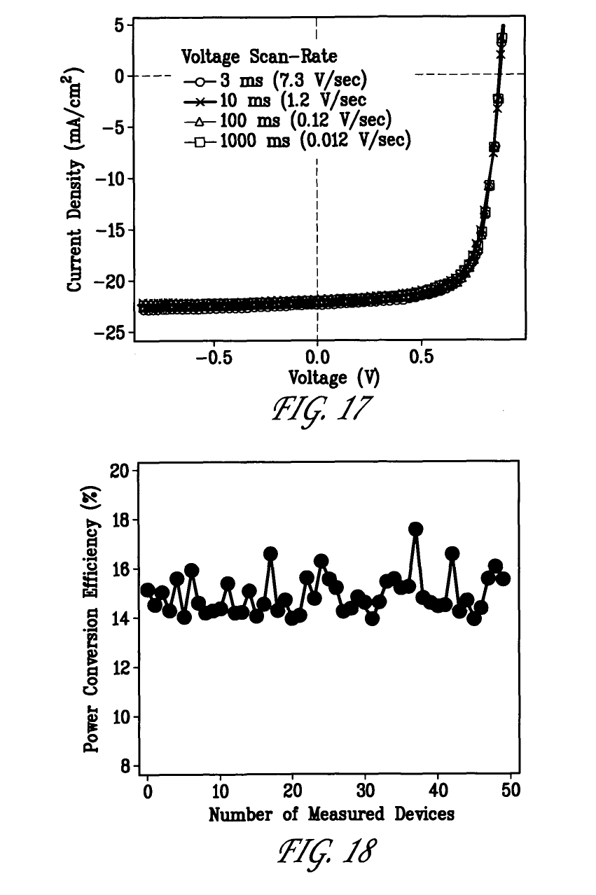

FIG. 14 and FIG. 15 provide graphs showing a correlation of the current density versus voltage performance of the solar cell devices in accordance with some embodiments, with hot-casting substrate temperature. The current density-voltage curves for devices fabricated at various temperatures were measured under simulated AM 1.5 irradiance at 100 mW/cm² (calibrated using a NIST certified monocrystalline Si solar cell (NEWPORT532, ISO1599). A mask was used to confine the illuminated active area to avoid edge effects. As FIG. 15 shows, a dramatic increase in the J_{sc} from a value of 3.5 mA/cm² to a value of 22.4 mA/cm² was observed, with an overall PCE from 1% to approximately 18%.

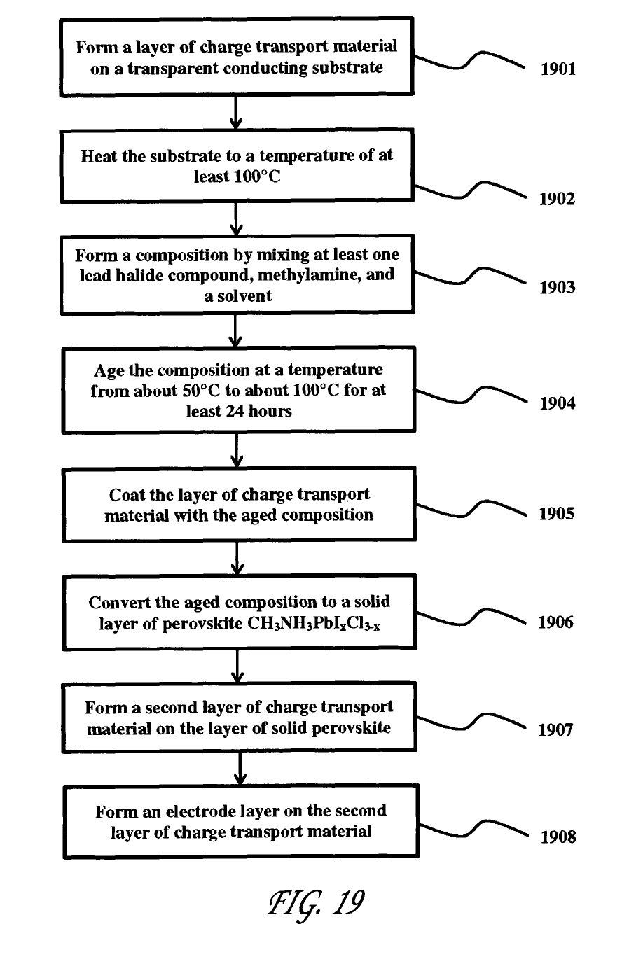

In addition to the high PCEs that were measured for the devices in accordance with some of the embodiments, it was also found that the current density for a solar cell prepared according to the present embodiment process was independent of the voltage sweep direction (FIG. 16) and scan rate (FIG. 17) for sweeping over 30 J-V scans. As a consequence, variations in the overall PCE were drastically reduced, ranging from approximately 14% to approximately 16% for 50 measured embodiment devices. The realization of high quality large area mm-scale crystalline grains might explain the observed increase in the overall PCE with high degree of reproducibility and negligible degradation with voltage sweep direction of scan rate. Presumably, the larger grain size leads to enhanced charge transport allowing for the photo-generated carrier to propagate through the device without frequent encounters with defects and impurities, which introduces losses by enhancing recombination and decreasing mobility. Also, an improved crystal quality of larger grains reduces self-doping, so that the wider depletion region can extract free carriers more efficiently before they recombine. Thus, larger grain sizes increase the current density without affecting the open circuit voltage.

The process for preparing thin films in accordance with some embodiments, and photovoltaic devices with these films, is expected to be applicable to the preparation of films of other materials besides those used in the various specific perovskite embodiments herein and may provide a solution to a long standing problem of overcoming polydispersity, defects and grain boundary recombination in solution-processed thin films. From the perspective of the global photovoltaics community, the process in accordance with some embodiments may be used for synthesizing wafer-scale crystalline perovskites for the fabrication of high-efficiency single-junction and hybrid (semiconductor and perovskite) tandem planar cells.

In summary, hybrid organic-inorganic perovskite thin films having crystalline grains with an average size of from about 1 millimeter to about 2 millimeters were prepared and employed in solar cells. The PCE values of these solar cells were from about 14% to about 18% and do not degrade with changes in the direction or the scan-rate of an applied voltage to the solar cell, which suggests that the large grain sizes may assist in reducing the influence of defect states on carrier recombination. Spectroscopic evidence supports that these relatively large grain sizes lead to good crystalline quality, low defect density, and high carrier mobility. The process for growing the hybrid organic-inorganic perovskites with low defect densities and high carrier mobilities may be applicable to other materials, overcoming problems related to polydispersity and defects and grain boundary recombination for solution-processed thin films for optoelectronic applications. The process is expected to be used for synthesizing wafer-scale crystalline perovskites for fabricating single junction and hybrid tandem planar solar cells. Finally, it is worth noting that the high values for the PCE were obtained in spite of using a sub-optimal layered structure (FIG. 3) in which the internal electric field is misaligned with respect to the absorption profile of the device.

While particular embodiments were chosen and described in order to best explain the principles of the invention and its practical application to thereby enable others skilled in the art to best utilize the invention in various embodiments, it will be understood it is not intended to limit the present application to these particular embodiments. On the contrary, the present application includes alternatives, modifications and equivalents that are suited to the particular use contemplated, and that are within the spirit and scope of the appended claims. It is intended that the scope of the invention be defined by the claims appended hereto.

1. A process for preparing a device, comprising:
forming a layer of charge transport material on a transparent conducting substrate;
heating the substrate to a temperature of at least 100° C.;
forming a composition by mixing at least one lead halide compound, methylamine, and a solvent;
aging the composition at a temperature from about 50° C. to about 100° C. for at least 24 hours,
coating the layer of charge transport material with the aged composition;
converting the aged composition to a solid layer of perovskite CH₃NH₃PbIₓCl₃₋ₓ, wherein 0≦x≦3, the solid layer having a plurality of grains with an average size of at least 50 micrometers;
forming a second layer of charge transport material on the layer of solid perovskite; and
forming an electrode layer on the second layer of charge transport material.

2. The process of claim 1, wherein the substrate comprises tin oxide.

3. The process of claim 1, wherein the lead halide compound is selected from PbI₂, PbCl₂, and combinations thereof.

4. The process of claim 1, wherein the solvent has a boiling point of 130° C. or higher.

5. The process of claim 1, wherein the device is a solar cell.

6. The process of claim 1, wherein the average grain size is at least 100 micrometers.

7. The process of claim 1, wherein the average grain size is at least 0.50 millimeters.

8. The process of claim 1, wherein the average grain size is from about 0.50 millimeters to about 2 millimeters.

9. The process of claim 1, wherein the average grain size is from about 1 millimeter to about 2 millimeters.

10. A device prepared by a process comprising the steps of:
forming a layer of charge transport material on a transparent conducting substrate;
heating the substrate to a temperature of at least 100° C.;
forming a composition by mixing at least one lead halide compound, methylamine, and a solvent;
aging the composition at a temperature from about 50° C. to about 100° C. for at least 24 hours,
coating the layer of charge transport material with the aged composition;
converting the aged composition to a solid layer of perovskite having grains with an average size of at least 50 micrometers;
forming a second layer of charge transport material on the layer of solid perovskite; and
forming an electrode layer on the second layer of charge transport material.

11. The device of claim 10, wherein the substrate comprises tin oxide.

12. The device of claim 10, wherein the lead halide compound is selected from PbI₂, PbCl₂, and combinations thereof.

13. The device of claim 10, wherein the solvent has a boiling point of 130° C. or higher.

14. The device of claim 10, wherein the device is a solar cell.

15. The device of claim 10, wherein:
the forming the layer of charge transport material on the transparent conducting substrate comprises forming a layer of poly(3,4-ethylenedioxythiophene):polystyrene sulfonic acid (PEDOT:PSS) on a substrate of indium tin oxide and thereafter performing the heating the substrate to a temperature of at least 100° C.;
the forming the composition comprises mixing a 1:1 molar ratio of lead iodide and methylamine in a solvent;
the aging the composition comprises aging the composition at a temperature of at least 50° C. for at least 24 hours;
the coating the layer of charge transport material comprises coating the PEDOT:PSS layer with the aged composition;
the converting the aged composition comprises forming a solid layer of perovskite CH₃NH₃PbIₓCl₃₋ₓ, wherein 0≦x≦3, the solid layer having a plurality of grains with an average size of at least 50 micrometers;
the forming the second layer of charge transport material comprises forming a layer of [6,6]-phenyl-C₆₀ butyric acid methyl ester (PCBM) on the solid layer of CH₃NH₃PbI₃; and
the forming the electrode layer comprises forming a metal electrode on the layer of PCBM.

16. The device of claim 15, wherein the substrate comprises tin oxide.

17. The device of claim 10, wherein the lead halide compound is selected from PbI₂, PbCl₂, and combinations thereof.

18. The device of claim 10, wherein the solvent has a boiling point of 130° C. or higher.

19. A process for preparing a perovskite thin film comprising the steps of:
heating a substrate to a temperature of at least 100° C.;
forming a composition by mixing at least one lead halide compound, methylamine, and a solvent;
aging the composition at a temperature from about 50° C. to about 100° C. for at least 24 hours;
coating the substrate with the aged composition; and
converting the aged composition to a solid layer of perovskite CH₃NH₃PbIₓCl₃₋ₓ, wherein 0≦x≦3, the solid layer having a plurality of grains with an average size of at least 50 micrometers.

20. The process of claim 19, wherein the lead halide compound is selected from PbI₂, PbCl₂, and combinations thereof.

21. (canceled)
